(19) United States
(12) Patent Application Publication
(10) Pub. No.: US 2014/0044976 A1
(43) Pub. Date: Feb. 13, 2014

(54) USE OF A MULTILAYER PVC/FLUORINATED POLYMER STRUCTURE FOR PROTECTING THE REAR OF SOLAR PANELS

(71) Applicants: Anthony Bonnet, Saint Laurent de Mure (FR); Samuel Devisme, Rouen (FR); Barbara Ramfel, Barc (FR); Stephane Bizet, Barc (FR)

(72) Inventors: Anthony Bonnet, Saint Laurent de Mure (FR); Samuel Devisme, Rouen (FR); Barbara Ramfel, Barc (FR); Stephane Bizet, Barc (FR)

(73) Assignee: ARKEMA FRANCE, Colombes (FR)

(21) Appl. No.: 14/113,034

(22) PCT Filed: Apr. 27, 2012
(86) PCT No.: PCT/FR12/50944

§ 371 Date: Oct. 21, 2013

(30) Foreign Application Priority Data
Apr. 27, 2011 (FR) 1153585

(51) Int. Cl. H01L 31/048

(52) U.S. Cl. CPC H01L 31/0487
USPC 428/422; 428/421

(57) ABSTRACT

The invention relates to a novel use of a multilayer structure, combining fluorinated polymers and PVC, as protection for use at the rear of a photovoltaic solar panel, said structure having improved durability in outdoor environments, while retaining the other properties associated with a back-sheet, namely good electric insulation, thermal stability in terms of volume and dimensions and good adhesion to the encapsulating material. The invention relates to the use of a multilayer structure as protection at the rear of a solar panel, said structure comprising at least one layer of fluorinated polymer and one layer of PVC.

The present invention relates generally to the field of multilayer films and in particular to multilayer structures based on fluorinated polymers and PVC. The invention also relates to the various processes for the manufacture of such structures, in particular by coextrusion or by coating, and to their use in the back protection of solar panels.

Solar panels or modules are arousing increasing interest, due to the renewable and nonpolluting nature of the energy thus obtained. A solar module comprises an assembly of photovoltaic cells consisting of optoelectronic components (usually based on crystalline silicon), which generate an electric voltage when exposed to light. The photovoltaic cells are placed between a transparent covering material, which is a sheet made of glass or of plastic, and a protective material at the rear, often a plastic film.

The protective film which will be positioned at the rear of the photovoltaic solar panel, known as back sheet, is exposed to an environment comprising factors as diverse as water, oxygen and/or UV radiation. The first function of a back sheet is thus to provide the solar panel with good electrical insulation, reduced transmission of water vapor, protection from UV radiation and oxygen-barrier properties. As the photocells are generally encapsulated in an encapsulant based on ethylene/vinyl acetate (EVA) copolymer or a thermoplastic encapsulant, another function of the back sheet consists in providing good adhesion to the EVA or to the thermoplastic encapsulant material, when these different materials are laminated together. Furthermore, the protective film has to be thermally stable in volume or dimensions in order to prevent thermal expansion and in particular shrinkage during the assembling of the cells.

Back sheets made of metal, in the form of sheets of steel or aluminum, are known. More recently, back sheets have been manufactured in polymeric materials, such as PET or TEDLAR® (material based on polyvinyl fluoride). The back sheets are generally composed of a polyester layer protected by two outer layers made of fluorinated polymer. The most widespread multilayer is assembled using polyurethane adhesives deposited by the solvent route: fluorinated polymer/adhesive/biaxially oriented PET/adhesive/fluorinated polymer. The biaxially oriented PET is a sheet with a thickness of 75 to 350 microns, while the fluorinated film which is a barrier to UV radiation (protection of the PET) has a thickness of 10 to 40 microns. There now exist on the market new films for back sheets using either a single fluorinated layer (for example: EVA/PET/fluorinated polymer) or no fluorinated layer (back sheet 100% PET, back sheet made of polyamide 12 (sold by Isovolta) or back sheet based on polyamide and polyolefin (Apolhya®)).

The PET films have the advantage of being dimensionally stable and have excellent electrical insulation characteristics. However, these films are sensitive to decomposition following exposure to environmental factors, such as UV radiation and moisture. It has turned out that the use of PET does not make it possible to obtain back sheets with good weatherability properties.

Attempts have thus been made to replace the PET layer with another polymer which confers greater resistance to moisture and to radiation, in other words which exhibits an improved weatherability when it is used in combination with a layer of fluorinated polymer. Such a polymer is represented by PVC, which is an inexpensive thermoplastic material which can be easily extruded and which exhibits, in comparison with PET, a better resistance to hydrolysis and a better stability towards UV radiation.

The present invention proposes to provide a novel use of a multilayer structure combining fluorinated polymers and PVC, as rear protection of a photovoltaic solar panel, which exhibits an improved weatherability while retaining the other properties of a back sheet, namely good electrical insulation, thermal stability in volume or dimensions and good adhesion to the encapsulant material.

To this end, a subject matter of the invention is the use, in the rear protection of a solar panel, of a multilayer structure comprising at least one layer of fluorinated polymer and one layer of PVC.

According to a first alternative embodiment, said multilayer structure consists of two layers, namely an outer layer comprising a fluorinated polymer and an inner layer of PVC.

“Outer layer” is understood to mean the layer which comes into contact with the external medium; “inner layer” is understood to mean the layer which comes into contact with the encapsulant material of the photovoltaic cell.

According to a second alternative embodiment, said multilayer structure consists of three layers, namely an outer layer of fluorinated polymer, an intermediate layer of PVC and an inner layer of fluorinated polymer.

Furthermore, in each of these alternative forms, a binder of acrylic, fluorinated or polyurethane type can be employed between the layer of fluorinated polymer and the layer of PVC.

In each of these alternative forms, said layer of fluorinated polymer can consist of a single film or of several films of fluorinated polymers. Likewise, the layer of PVC can consist of a single film or of several films of PVC.

These structures can be produced by coextrusion, by coating or by lamination with adhesives.

The invention will now be described in detail.

The present invention relates to the use, for the back protection of a solar panel, of a multilayer structure comprising at least one layer of fluorinated polymer and one layer of PVC, in which each layer of fluorinated polymer comprises a homopolymer of VDF or a copolymer of VDF and of a fluorinated comonomer which can copolymerize with VDF.

The fluorinated polymer is a homopolymer or a copolymer of VDF and of a fluorinated comonomer which can copolymerize with VDF. Each layer of fluorinated polymer thus consists of a VDF-based polymer.

Advantageously, the fluorinated comonomer which can copolymerize with VDF is chosen, for example, from vinyl fluoride; trifluoroethylene (VF3); chlorotrifluoroethylene (CTFE); 1,2-difluoroethylene; tetrafluoroethylene (TFE); hexafluoropropylene (HFP); perfluoro(alkyl vinyl) ethers, such as perfluoro(methyl vinyl) ether (PMVE), perfluoro(ethyl vinyl) ether (PEVE) and perfluoro(propyl vinyl) ether (PPVE); perfluoro(1,3-dioxole); perfluoro(2,2-dimethyl-1,3-dioxole) (PDD); and their mixtures.

Preferably, the fluorinated comonomer is chosen from chlorotrifluoroethylene (CTFE), hexafluoropropylene (HFP), trifluoroethylene (VF3), tetrafluoroethylene (TFE), and their mixtures. The comonomer is advantageously HFP as it copolymerizes well with VDF and makes it possible to introduce good thermomechanical properties. Preferably, the copolymer comprises only VDF and HFP.

Preferably, the fluorinated polymer is a VDF homopolymer (PVDF) or a VDF copolymer, such as VDF-HFP, comprising at least 50% by weight of VDF, advantageously at least 75% by weight of VDF and preferably at least 90% by weight of VDF. Mention may more particularly be made, for example, of the following homopolymers or copolymers of VDF comprising more than 75% of VDF and the remainder of HFP: Kynar® 710, Kynar® 720, Kynar ® 740, Kynar Flex® 2850 or Kynar Flex® 3120, sold by Arkema.

Advantageously, the VDF homopolymer or copolymer has a viscosity ranging from 100 Pa·s to 3000 Pa·s, the viscosity being measured at 230° C., at a shear gradient of 100 s⁻¹, using a capillary rheometer. This is because this type of polymer is well suited to extrusion. Preferably, the polymer has a viscosity ranging from 500 Pa·s to 2900 Pa·s, the viscosity being measured at 230° C., at a shear gradient of 100 s⁻¹, using a capillary rheometer,

In one embodiment, the fluorinated polymer comprises at least one additive in the form of an additional polymer which can be a homopolymer or copolymer of methyl methacrylate (MMA), optionally with the addition of inorganic particles.

The layer of fluorinated polymer can comprise one or more fillers formed of inorganic and/or organic particles, in addition to the presence of the additional MMA polymer.

As regards the MMA polymer, use is advantageously made of homopolymers of methyl methacrylate (MMA) and copolymers comprising at least 50% by weight of MMA and at least one other monomer which can copolymerize with MMA.

Mention may be made, as examples of comonomers which can copolymerize with MMA, of alkyl(meth)acrylates, acrylonitrile, butadiene, styrene or isoprene. Examples of alkyl(meth)acrylates are described in Kirk-Othmer, Encyclopedia of Chemical Technology, 4th edition (1991), in Vol. 1, pages 292-293, and in Vol. 16, pages 475-478.

Advantageously, the MMA polymer (homopolymer or copolymer) comprises, by weight, from 0 to 20% and preferably from 5 to 15% of C₁-C₈ alkyl(meth)acrylate, which is preferably methyl acrylate and/or ethyl acrylate. The MMA polymer (homopolymer or copolymer) can be functionalized, that is to say that it comprises acid, acid chloride, alcohol or anhydride functional groups. These functional groups can be introduced by grafting or by copolymerization. Advantageously, the functionality is in particular the acid functional group introduced by the acrylic acid comonomer. Use may also be made of a monomer comprising two neighboring acrylic acid functional groups which can be dehydrated to form an anhydride. The proportion of functionality can be from 0 to 15% by weight of the MMA polymer, preferably from 0 to 10% by weight.

The MMA polymer can advantageously comprise at least one impact-modifying additive. There exist commercial grades of “impact-resistant” MMA polymer, which comprise an acrylic impact-modifying additive in the form of multilayer particles. The impact-modifying additive is then present in the MMA polymer as marketed (that is to say, introduced into the MMA resin during the manufacturing process) but it can also be added during the manufacture of the film. The proportion of impact-modifying additive varies from 0 to 30 parts per 70 to 100 parts of MMA polymer, the total forming 100 parts.

The impact-modifying additives of the type consisting of multilayer particles, also commonly known as core-shell particles, comprise at least one elastomeric (or soft) layer, that is to say a layer formed of a polymer having a glass transition temperature (Tg) of less than −5° C., and at least one rigid (or hard) layer, that is to say formed of a polymer having a Tg of greater than 25° C. The size of the particles is generally less than a μm and advantageously between 50 and 300 nm. Examples of an impact-modifying additive in the form of multilayer particles of core-shell type will be found in the following documents: EP 1 061 100 A1, US 2004/0030046 A1, FR-A-2 446 296 or US 2005/0124761 A1. Preference is given to particles of core-shell type having at least 80% by weight of soft elastomerie phase.

The MVI (melt volume index) of the MMA polymer can be between 2 and 25 cm³/10 min, measured at 230° C. under a load of 3.8 kg.

The content of MMA polymer in the layer of fluorinated polymer is between 1 and 55% by weight, advantageously between 2 and 40% by weight, preferably between 3 and 25% by weight.

As regards the inorganic particles, use may be made of a metal oxide, such as, for example, titanium dioxide (TiO₂), zinc oxides or zinc sulfides, silica, quartz, alumina, a carbonate, such as, for example, calcium carbonate, talc, mica, dolomite (CaCO₃.MgCO₃), montmorillonite (aluminosilicate), BaSO₄, ZrSiO₄, Fe₃O₄, and their mixtures.

These particles have the function of opacifying the composition in the UV/visible region. A TiO₂ filler is very particularly preferred from that viewpoint. The mineral filler, for example of TiO₂ type, acts as sunscreen in order to have an opaque film, mainly by scattering/reflection of UV radiation, but also visible light.

It is possible to combine an organic UV absorber with the inorganic particles in order to reinforce the protection against UV radiation, for example benzophenones or benzotriazoles. Tinuvin® 234 is particularly preferred.

Particles pigmented black can also be added. They are carbon black or else carbon nanotubes, used at contents below their percolation threshold.

These particles have a size, expressed as mean diameter, generally of between 0.05 and 20 microns, advantageously between 0.1 μm and 10 μm, preferably between 0.2 μm and 5 μm. The content of inorganic particles in the layer of fluorinated polymer is between 0.1 and 30% by weight, advantageously between 5 and 28% by weight, preferably between 10 and 27% by weight and more preferably still between 15 and 25% by weight.

According to the invention, the composition of the layer of fluorinated polymer can be prepared by any method which makes it possible to obtain a homogeneous mixture of the polymers and optional additives and/or fillers participating in the composition of the layer of fluorinated polymer.

Mention may be in particular be made, among these methods, of melt extrusion, compacting or roll kneading.

More particularly, the composition according to the invention is prepared by melt blending all the polymers and optional additives and fibers and is then transformed, for example in the form of granules, by compounding on a device known to a person skilled in the art, such as a twin-screw extruder, a co-kneader or a mixer. This composition can either be coextruded with another material or extruded in the form of a film.

The thickness of the layer of fluorinated polymer varies from 10 to 150 microns, preferably from 15 to 40 microns, limits included,

The PVC layer consists of rigid, semirigid or plasticized PVC. The PVC can be any vinyl chloride polymer or copolymer: vinyl chloride homopolymer, optionally chlorinated (CPVC), and copolymers, optionally crosslinked, resulting from the copolymerization of vinyl chloride with one or more unsaturated ethylenic comonomers. The latter are chosen from: vinylidene chloride, vinylidene fluoride, vinyl carboxylates, such as vinyl acetate, vinyl propionate or vinyl butyrate, acrylic and methacrylic acids, nitriles, amides and alkyl esters derived from acrylic and methacrylic acids, in particular acrylonitrile, acrylamide, methacrylamide, methyl methacrylate, methyl acrylate, butyl acrylate, ethyl acrylate or 2-ethylhexyl acrylate, vinylaromatic derivatives, such as styrene, or olefins, such as ethylene, propene or 1-butene.

Fillers, in particular mineral fillers, can also be added to the PVC to improve the thermomechanical strength of the composition. In a nonlimiting way, silica, alumina or calcium carbonates or carbon nanotubes or also glass fibers will be given as examples.

The preferred PVCs are vinyl chloride homo- and copolymers. Advantageously, the latter have a heat transmission coefficient U of approximately 65 W/m²K.

The PVC, CPVC or PVC/CPVC layer can comprise, by weight:
from 50 to 82% by weight of one or more PVC and/or CPVC resins. The coefficient U of the PVC resin can be between 50 and 100 W/m²K. Such a resin is obtained by a suspension, bulk, emulsion or microsuspension polymerization process. The coefficient U of the CPVC resin, obtained by a process of chlorination of a bulk PVC resin, can be between 60 and 70 W/m²K;
from 0.1 to 30% of additives chosen from stabilizers, processing aids, lubricants or flame retardants. In particular, mention may be made, among the additives commonly used in compositions based on vinyl resin, of organic carboxylic acid metal salts, organic phosphoric acids, zeolites, hydrotalcites, epoxidized compounds, β-diketones, polyhydric alcohols, phosphorus, sulfur-comprising or phenolic antioxidants, ultraviolet absorbers, for example benzophenones, benzotriazoles and oxanilide derivatives, cyanoacrylates, hindered amine light stabilizers (HALS), perchloric acid salts, and other inorganic compounds based on metals, lubricants, for example organic waxes, fatty alcohols, fatty acids, esters, metal salts, fillers, for example chalk or talc, and pigments, such as titanium dioxide;
from 0 to 11% of opacifying filler, such as, for example, titanium dioxide, zinc oxide or zinc sulfide;
from 0 to 20% of one or more plasticizers;
from 0 to 20% of thermoplastic compound based on acrylonitrile or acrylate;
from 0 to 20% of glass fibers.

The plasticizer(s) employed in the PVC, CPVC or PVC/CPVC layer is (are) chosen from the group consisting of azelates, trimellitates, sebacates, adipates, phthalates, citrates, benzoates, tallates, glutarates, fumarates, maleates, oleates, palmitates, acetates, epoxidized soybean oil and their mixtures.

In order to reinforce the thermomechanical strength of the PVC, one or more woven or nonwoven substrates can be used in combination with the latter. These substrates can consist of glass fiber, carbon fiber, polymer fibers (such as polyester, polyamide, and the like) or natural fibers (flax, hemp and the like). In this case, the PVC layer is formed of the PVC-substrate combination.

The thermoplastic compound employed in the PVC, CPVC or PVC/CPVC layer is preferably a thermoplastic compound based on acrylonitrile or acrylate. It can be obtained from compounds chosen from styrene/acrylonitrile, acrylonitrile/styrene/acrylate or ethylene/methyl acrylate copolymers.

The PVC, CPVC or PVC/CPVC layer makes it possible to guarantee good preservation of the thermomechanical strength up to the lamination temperature of the solar panel (120-150° C., 5-30 minutes) and also good resistance to UV aging.

The method of transformation used in order to obtain this PVC, CPVC or PVC/CPVC layer is preferably extrusion in a temperature range between 100° C. and 180° C., indeed even 220° C. The thickness of the PVC, CPVC or PVC/CPVC layer thus obtained varies from 150 to 450 microns, preferably from 200 to 300 microns, limits included. An example of a PVC composition is given in the following table 1:

TABLE 1

| Constituents | % by weight |
|---|---|
| Lacovyl GB 1040 (PVC resin) | 71.1 |
| Micromya (CaCO₃ filler) | 7.9 |
| Kane ACE B 382 (impact modifier) | 2.1 |
| Plastistrength 770 (processing aid) | 0.7 |
| Internal lubricant | 1.1 |
| External lubricant | 0.3 |
| Ca/Zn (heat stabilizer) | 3.9 |
| Kronos 2220 (TiO₂) | 2.6 |
| Glass fibers (reinforcing filler) | 10.3 |
| Total | 100 |

The use of the PVC in a back sheet consisting of a multilayer structure introduces numerous advantages:
a competitive price comparable to the structures comprising PET;
better resistance to hydrolysis than PET;
improved stability toward UV radiation in comparison with PET;
excellent fire properties (V0 according to the UL94 standard). This is an advantage in the ease of solar panels integrated in buildings (BIPVs);
electrical properties satisfactory for the PV specifications;
manufacture of the back sheet in a single stage.

The use of multilayer structures combining fluorinated polymers with PVC makes it possible to obtain back sheets for a photovoltaic module having the following main characteristics:
good water-barrier properties (<1 g/m²/2.4 h for 200 microns);
excellent electrical properties (high maximum operating voltage determined by a partial discharge test, high dielectric strength);
low shrinkage (less than 3% at 150° C.);
good thermomechanical properties up to the lamination temperature of the solar panel (120° C.-150° C.);
good fire properties;
a creep strength correct for a temperature of between 85 and 150° C.;
adhesion to the encapsulant films (EVA, polyolefins and the like);
ease of adding colored pigments/UV barriers.

In order to simulate the extreme stresses encountered by a back sheet during the lamination phase, the protocol below is applied.

The following tests were carried out on composition samples with a thickness of 300 μm. The samples were prepared from a mixture of the different worked starting materials, in proportions as defined in the table below, on a two-roll mixer at 205° C. for 5 minutes. The material was then compressed under a press at 185° C. under a pressure of 200 bar for 240 seconds.

The test consists of a measurement of the shrinkage. Before the measurements, the sample has to be left standing at ambient temperature for a minimum of 2 h. A benchmark is plotted in the longitudinal direction and in the transverse direction on a 140×140 mm plate, at 20 mm from the edges. The middle of the square thus obtained is marked. The longitudinal and transverse distances (respectively L0 and T0) obtained at the center of the square are marked and measured. The sample is placed on a wooden board of appropriate dimensions and then the whole assembly is introduced into an oven at the specified temperature for a given time. Once the time has elapsed, the sample is withdrawn from the oven and left standing for a minimum of 30 minutes under the same conditions used for the conditioning of the sample before the test. The longitudinal and transverse distances (respectively L and T) are then remeasured.

The shrinkage can then be calculated according to the following formulae (see standard NF EN ISO 11 501):

Longitudinal shrinkage ΔL=(L0−L))*100/L0

Transverse shrinkage ΔT=(T0−T)*100/T0.

The PVC, CPVC or PVC/CPVC layer in accordance with the invention makes it possible to obtain shrinkage values of between 0.85 and 2.7%, as shown in table 2 below:

TABLE 2

| | A | B | C | D | E | F | G |
|---|---|---|---|---|---|---|---|
| U coefficient of the | 65 | 65 | 65 | 65 | 65 | 70 | 65 |
| PVC | | | | | | | |
| % TiO₂ | 2.5 | 10 | 0.8 | 2.5 | 2.5 | 2.7 | 2.6 |
| % Glass fiber | 0 | 0 | 20 | 10 | 0 | 0 | 10 |
| % Filler | 0 | 0 | 0 | 0 | 7.7 | 7.7 | 8 |
| Shrinkage at 140° C. | 1.9 | 1.7 | 0.85 | 1.05 | 2.7 | 1.05 | 1.25 |
| (30 min) % | | | | | | | |
| Shrinkage at 150° C. | 2.7 | 2.3 | 1.05 | 1.7 | 2.1 | 1.9 | 1.45 |
| (15 min) % | | | | | | | |

The examples of multilayer structures presented below, which illustrate the invention, are not exhaustive. They can all be used as back sheet for protecting the back face of solar panels (SiC, thin layer, and the like).

In these examples, the following products were used as fluorinated polymers:
Kynar 740: vinylidene fluoride homopolymer having a melting point (M.p.) of 169° C. and an elastic modulus of 1700 MPa;
Kynar Flex 3120-50, having a melting point of 165° C. and an elastic modulus of 690 MPa.

The M.p. values were measured by DSC or differential scanning calorimetry. The elastic moduli were measured according to the standard ISO 527.

The PMMA used in the compositions below is PMMA Altuglas BS 550 (copolymer of methyl methacrylate and of ethyl acrylate—MFR. 17-20 g/10 min (230° C.; 3.8 kg)).

Elastollan C85 is a polyester-based polyurethane.

### 1. EXAMPLES OF STRUCTURES OBTAINED BY COEXTRUSION

The multilayer films were produced by calendaring (CAST) on an extrusion line of Amut brand. This line is composed of three extruders:
a conical twin-screw extruder with a diameter of 60 mm of the Kraus Maffei brand which is special for the extrusion of the PVC,
a single-screw extruder with a diameter of 45 mm of Samafor brand for the extrusion of the PVDF or of the binder,
a single-screw extruder with a diameter of 30 mm of Dr Collin brand for the extrusion of the outer PVDF layer.

The line is also equipped with a Verbugren multimanifold die of 500 mm. The multimanifold system makes possible the production of a three-layer film or sheet (Layer 1/Layer 2/Layer 3) with a variable distribution of thicknesses (example: 30/30/350 microns). The process parameters were set as shown below:
T° extrusion layer 1 and 2; 240° C.
T° extrusion layer 3: 180° C.
T° of the die: 200° C.
the line speed is 3 m/min.

The following examples of structures according to the invention were obtained by coextrusion:

1.1—CPVC or PVC/PMMA V0825 50%—Kynar Flex 3120-50 50%/Kynar 740 (350/10/30 microns)

The inner layer is produced by dry blending at the base of the machine at the time of production.

1.2—CPVC or PVC/PMMA V0825 50%—Kynar Flex 3120-50 50%/Kynar 740 60%—PMMA 24%—TiO₂ 16%

The inner layer is produced by dry blending at the base of the machine at the time of production. The PVDF outer layer comprising TiO₂ is produced by compounding in a co-kneader at a temperature not exceeding 240° C. In a first step, a PMMA/TiO₂ masterbatch is prepared on a twin-screw extruder; the masterbatch is subsequently blended with the PVDF in the co-kneader or in the twin-screw extruder.

1.3—CPVC or PVC/Kynar 740 40%—PMMA 44%—TiO₂ 16%/Kynar 740

The inner layer comprising TiO₂ is produced by compounding as described for example 1.2.

1.4—CPVC or PVC/PMMA 35%—Kynar 740 35%—Modifier S2001 (Mitsubishi Rayon) 30%/Kynar 740 60%—PMMA 24%—TiO₂ 16%

The inner layer comprising modifier S2001 is prepared by compounding in a twin-screw extruder. The outer layer comprising TiO₂ is produced by compounding as described above for 1.2.

1.5—CPVC or PVC/PMMA 50%—PVDF 50%/PVDF 73.3%—PMMA 4.7%—ZnO 15%—TiO₂ 7%

The outer layer comprising TiO, and ZnO is produced by compounding. The introduction of TiO₂ into the PVDF necessitates the preparation beforehand of a PMMA/TiO₂ masterbatch on a twin-screw extruder; this masterbatch is subsequently blended with the PVDF in the co-kneader or in the twin-screw extruder.

1.6—CPVC or PVC/PVDF 60%—PMMA 24%—TiO₂ 16%

The outer layer comprising TiO₂ is produced by compounding as described for 1.2.

1.7—CPVC or PVC/PVDF 60%—PMMA 16%—ZnO 24%

The outer layer comprising ZnO is produced by compounding in a twin-screw extruder.

1.8—CPVC or PVC/Elastollan C85/Kynar 740 60%—PMMA 24%—TiO₂ 16%

The outer layer comprising TiO₂ is produced by compounding as described for 1.2.

1.9—CPVC or PVC Elastollan C85/Kynar 740 73.3%—PMMA 4.7%—ZnO 15%—TiO₂ 7%

The introduction of TiO₂ into the PVDF requires the preparation beforehand of a PMMA/TiO₂ masterbatch on a twin-screw extruder; this masterbatch is subsequently blended with the PVDF in the co-kneader or in the twin-screw extruder.

1.10—Kynar 740 60%—PMMA 24%—TiO₂ 16% CPVC or PVC/Elastollan C85/Kynar 740 60%—PMMA 24%—TiO₂ 16%

The outer layer comprising TiO₂ is produced by compounding as described for 1.2.

1.11—PVDF 73.3%—PMMA 4.7%—ZnO 15%—TiO₂ 7%/CPVC or PVC PMMA 50%—PVDF 50%/PVDF 73.3%—PMMA 4.7%—ZnO 15%—TiO₂ 7%

The outer layer comprising TiO₂ and ZnO is produced by compounding. The introduction of TiO₂ into the PVDF requires the preparation beforehand of a PMMA/TiO₂ masterbatch on a twin-screw extruder; this masterbatch is subsequently blended with the PVDF in the co-kneader or in the twin-screw extruder.

### 2. EXAMPLES OF STRUCTURES OBTAINED BY EXTRUSION COATING

The structures produced by extrusion coating are produced on an extrusion line of the Dr Collin brand. This line is composed of three extruders equipped with a standard polyolefin screw profile, with a variable coextrusion block and with a 250 mm coathanger die, The coextrusion block allows the production of a film of 1 to 5 layers with a variable distribution of thicknesses (example: 30/250 microns). A system of paying-out devices makes it possible to unwind various supports, including a PVDF film, The process parameters were set as indicated below:
T° extrusion layer 1: 200° C.
T° extrusion layer 2: 180° C.
coextrusion box and die: 200° C.

The line speed is 2 m/min.

Examples of structures produced by extrusion coating or extrusion lamination:
2.1—CPVC or PVC/Elastollan C85 (polyester-based TPU) (30/250 microns): film coextruded and then coated onto a multilayer Kynar film having a thickness of 30 microns (PVDF/Kynar 740 40%—PMMA 44%—TiO₂ 16%/PVDF 5/20/5 microns).
2.2—CPVC or PVC/Elastollan C85 (polyester-based TPU) (30/250 microns): film coextruded and then coated onto a monolayer film with a thickness of 18 μm (Kynar 740 73.3%—PMMA 4.7%—ZnO 15%—TiO₂ 7%),
2.3—CPVC or PVC/Elastollan C85 (polyester-based TPU) (30/250 microns): film coextruded and then laminated between two multilayer films with a thickness of 30 microns (PVDF/Kynar 740 40%—PMMA 44%—TiO₂ 16%/PVDF 5/20/5 microns).
2.4—CPVC or PVC/Elastollan C85 (polyester-based TPU) (30/250 microns): film coextruded and then laminated between two monolayer films with a thickness of 18 μm (Kynar 740 73.3% PMMA 4.7%—ZnO 15%—TiO₂ 7%).

The Kynar films are produced beforehand by the blown film technique on a 5-layer tubular line of Dr Collin brand equipped with a pancake-type die.

### 3. EXAMPLES OF STRUCTURES OBTAINED BY LAMINATION (ADHESIVE)

The multilayer structures can also be assembled by solvent-based adhesives in two stages according to the following protocol:

i) Extrusion of the Films
CPVC film with a thickness of 250 microns produced by flat-film extrusion, according to a technique known to a person skilled in the art;
Kynar film 1: multilayer film with a thickness of 30 microns (PVDF/Kynar 740 60%—PMMA 24%—TiO₂ 16%/PVDF 5/20/5 microns);
Kynar film 2: monolayer film with a thickness of 18 μm (Kynar 740 73.3%—PMMA 4.7%—ZnO 15%—TiO₂ 7%).

The films 1 and 2 are produced beforehand by the blown film technique on a 5-layer tubular line of Dr Collin brand equipped with a pancake-type die.

ii) Application of the Adhesives

The targeted structure (PVC film (350 microns)/adhesive/PVDF film (film 1 or 2)) is produced in the following way:
a bar coater is used to apply, to the PVC sheet, a layer of adhesive (not dried) with a thickness of 30 microns. The formulation of the adhesive used is as follows: (supplier Bostick): HBTS ESP 877 (100 parts)+Biscodur 1621 curing agent (9 parts). The PVC sheet coated with adhesive is subsequently left at ambient temperature for one minute and then at 50° C. for 5 mm.
The Kynar film is subsequently laminated by hand onto the PVC sheet coated with a layer of adhesive;
the structure is subsequently compressed at 80° C., 5 min, 3 bar.

Before being tested or used, the structure is subsequently left in an oven at 60° C. for 3 days with the objective of completely crosslinking the adhesive.

The following structures were obtained by lamination:

3.1—CPVC or PVC/two-component PU ester solvent-based adhesive/Kynar film 1;

3.2—CPVC or PVC/two-component PU ester solvent-based adhesive/Kynar film 2;

3.3—Kynar film 1/two-component PU ester solvent-based adhesive/CPVC or PVC/two-component PU ester solvent-based adhesive/Kynar film 1;

3.4—Kynar film 2/two-component PU ester solvent-based adhesive/CPVC or PVC/two-component PU ester solvent-based adhesive/Kynar film 2.

### 4. EXAMPLE OF THE MANUFACTURE OF A MULTILAYER PVC SHEET

A PVC/glass fiber fabric/PVC (150 μm/50 μm/150 μm) multilayer structure is produced by hot thermal lamination of two PVC sheets on the glass fabric using a calendaring line. The PVC sheet is preheated on thermostatically controlled rolls and is then thermally laminated in a calender. The temperatures, the clamping force of the calender and the line speed are adjusted as a function of the PVC formulation and of the glass fabric used.

### ABBREVIATIONS

PV—photovoltaic

PVC—generic term encompassing polyvinyl chloride and its derivatives, in particular chlorinated derivatives, such as CPVC

CPVC—chlorinated polyvinyl chloride

back sheet—back face of a photovoltaic panel

PVDF—polyvinylidene fluoride

PET—polyethylene terephthalate

MMA—methyl methacrylate

M.p.—melting point

MVI—melt volume index

MFR—melt flow rate, expressed in g/min

1. A solar panel backsheet, having a multilayer structure comprising at least one layer of fluorinated polymer and one layer of polyvinylidene chloride (PVC), in which said fluorinated polymer is a homopolymer of vinylidene chloride (VDF) or a copolymer of VDF and of a fluorinated comonomer which can copolymerize with VDF.

2. The solar panel backsheet as claimed in claim 1, in which the fluorinated comonomer which can copolymerize with VDF is selected from the group consisting of vinyl fluoride, trifluoroethylene, chlorotrifluoroethylene, 1,2-difluoroethylene, tetrafluoroethylene, hexafluoropropylene (HFP), perfluoro(alkyl vinyl) ethers, perfluoro(methyl vinyl) ether, perfluoro(ethyl vinyl) ether, perfluoro(propyl vinyl) ether, perfluoro(1,3-dioxole), perfluoro(2,2-dimethyl-1,3-dioxole, and mixtures thereof.

3. The solar panel backsheet as claimed in claim 1, in which said copolymer is a VDF-HFP copolymer comprising at least 50% by weight of VDF.

4. The solar panel backsheet as claimed in claim 1, in which the fluorinated polymer additionally comprises at least one homopolymer or copolymer of methyl methacrylate.

5. The solar panel backsheet as claimed in claim 4, in which said fluorinated polymer additionally comprises inorganic particles selected from the group consisting of titanium dioxide, zinc oxides, zinc sulfides, silica, quartz, alumina, calcium carbonate, talc, mica, dolomite, montmorillonite, BaSO₄, ZrSiO₄, Fe₃O₄, and their mixtures.

6. The solar panel backsheet as claimed in claim 1, in which the PVC is a polymer chosen from vinyl chloride homopolymers, chlorinated (CPVC), and copolymers, optionally crosslinked, resulting from the copolymerization of vinyl chloride with one or more unsaturated ethylenic comonomers.

7. The solar panel backsheet as claimed in claim 6, in which said unsaturated ethylenic comonomers are selected from the group consisting of: vinylidene chloride, vinylidene fluoride, vinyl acetate, vinyl propionate, vinyl butyrate, acrylic acids, methacrylic acids, nitriles, acrylonitrile, acrylamide, methacrylamide, methyl methacrylate, methyl acrylate, butyl acrylate, ethyl acrylate, 2-ethylhexyl acrylate, styrene, ethylene, propene and 1-butene.

8. The solar panel backsheet as claimed in claim 1, in which said multilayer structure consists of two layers, namely an outer layer comprising a fluorinated polymer and an inner layer of PVC.

9. The solar panel backsheet as claimed in claim 1, in which said multilayer structure consists of three layers, namely an outer layer of fluorinated polymer, an intermediate layer of PVC and an inner layer of fluorinated polymer.

10. The solar panel backsheet as claimed in claim 1, in which a acrylic, fluorinated or polyurethane binder is placed between the layer of fluorinated polymer and the layer of PVC.

11. The solar panel backsheet as claimed in as claimed in claim 1, in which said layer of fluorinated polymer consists of a single film or of several films of fluorinated polymers.

12. The solar panel backsheet as claimed in claim 1, in which said PVC layer consists of a single film or of several films of PVC.

13. The solar panel backsheet as claimed in claim 1, in which said multilayer structure is manufactured by coextrusion.

14. The solar panel backsheet as claimed in claim 1, in which said multilayer structure is manufactured by extrusion coating.

15. The solar panel backsheet as claimed in claim 1, in which said multilayer structure is manufactured by lamination.

16. The solar panel backsheet as claimed in claim 3, in which said copolymer is a VDF-HFP copolymer comprising at least 75% by weight of VDF.

17. The solar panel backsheet as claimed in claim 16, in which said copolymer is a VDF-HFP copolymer comprising at least 90% by weight of VDF.
